(19) United States
(12) Patent Application Publication
(10) Pub. No.: US 2013/0102141 A1
(43) Pub. Date: Apr. 25, 2013

(54) METHOD FOR MANUFACTURING SEMICONDUCTOR DEVICE

(71) Applicant: Sumitomo Electric Industries, Ltd., Osaka-shi (JP)

(72) Inventors: Hiromu SHIOMI, Osaka-shi (JP); Mitsuru SHIMAZU, Osaka-shi (JP)

(73) Assignee: SUMITOMO ELECTRIC INDUSTRIES, LTD., Osaka-shi (JP)

(21) Appl. No.: 13/658,541

(22) Filed: Oct. 23, 2012

Related U.S. Application Data
(60) Provisional application No. 61/550,678, filed on Oct. 24, 2011.
(60) Provisional application No. 61/577,424, filed on Dec. 19, 2011.

(30) Foreign Application Priority Data
Dec. 19, 2011 (JP) 2011-276686

(51) Int. Cl. H01L 21/283

(52) U.S. Cl. 438/590; 257/E21.19

(57) ABSTRACT

A method for manufacturing a MOSFET includes the steps of preparing a substrate (10) composed of silicon carbide, forming a gate oxide film (20) in contact with the substrate (10), and introducing nitrogen atoms in a region including an interface between the substrate (10) and the gate oxide film (20). Then, in the step of introducing nitrogen atoms, the substrate (10) on which the gate oxide film (20) has been formed is heated in an atmospheric gas formed by heating a nitriding process gas containing nitrogen atoms but not containing oxygen atoms to a temperature exceeding 1200° C., so that nitrogen atoms are introduced in the region including the interface between the substrate (10) and the gate oxide film (20).

### BACKGROUND OF THE INVENTION

1. Field of the Invention

The present invention relates to a method for manufacturing a semiconductor device, and more specifically to a method for manufacturing a semiconductor device capable of improving channel mobility.

2. Description of the Background Art

In recent years, in order to achieve a higher breakdown voltage, lower loss, and the like of a semiconductor device, silicon carbide has increasingly been adopted as a material for forming a semiconductor device. Silicon carbide is a wide band-gap semiconductor greater in band gap than silicon conventionally widely used as a material for forming a semiconductor device. Therefore, by adopting silicon carbide as a material for forming a semiconductor device, a higher breakdown voltage, a lower ON resistance, and the like of the semiconductor device can be achieved.

Examples of semiconductor devices adopting silicon carbide as a material include a MOSFET (Metal. Oxide Semiconductor Field Effect Transistor) and the like. A MOSFET is a semiconductor device controlling whether or not to form an inversion layer in a channel region with a prescribed voltage being defined as a threshold, to thereby allow conduction or cut-off of a current, and it is manufactured by forming a gate oxide film, an electrode, and the like on a substrate where an active region is formed. Meanwhile, a MOSFET suffers a problem of lowering in channel mobility due to interface state density present in a region including an interface between a substrate and a gate oxide film. In order to address this, for example, a method for manufacturing a MOSFET including the step of introducing nitrogen atoms in such a region above by heating a substrate in a nitriding process gas such as NO (nitrogen monoxide) or N₂O (nitrous oxide) has been proposed (see, for example, U.S. Pat. No. 7,709,403 (Patent Literature 1) and V. V. Afanas'ev et al., “Mechanisms responsible for improvement of 4H-SiC/SiO₂ Interface properties by nitridation,” APPLIED PHYSICS LETTERS, (the United States), American Institute of Physics, Jan. 27, 2003, Vol. 82, No. 4, pp. 568-570 (Non Patent Literature 1)).

In the methods proposed in Patent Literature 1 and Non Patent Literature 1, in the step of introducing nitrogen atoms, the substrate is heated in a nitriding process gas containing nitrogen atoms and oxygen atoms such as NO or N₂O. Therefore, when the substrate is heated at a high temperature, the nitriding process gas is thermally decomposed and oxygen is generated. Then, oxidation proceeds while nitrogen atoms are introduced in the region including the interface between the substrate and the gate oxide film, and consequently interface state density present in the region above cannot sufficiently be lowered and it becomes difficult to manufacture a MOSFET having desired channel mobility. On the other hand, a method for manufacturing a MOSFET including the step of introducing nitrogen atoms in the region above, for example, by heating the substrate in a nitriding process gas containing NO or N₂O and thereafter further heating the substrate in a nitriding process gas not containing oxygen atoms such as NH₃ (ammonia) has been proposed (see, for example, U.S. Pat. No. 7,022,378 (Patent Literature 2) and Junji Senzaki et al., “Challenges of high-performance and high-reliability in SiC MOS structures,” International Conference on Silicon Carbide and Related Materials Abstract Book, (the United States), Sep. 15, 2011, p. 265 (Non Patent Literature 2)).

As described above, with the methods proposed in Patent Literatures 1 and 2 and Non Patent Literatures 1 and 2, in the step of introducing nitrogen atoms in the region including the interface between the substrate and the gate oxide film, the substrate is heated in a nitriding process gas containing nitrogen atoms and oxygen atoms such as NO or N₂O. Therefore, when the substrate is heated at a high temperature, oxidation proceeds in the region including the interface between the substrate and the gate oxide film. Thus, with these methods, interface state density present in the region above cannot sufficiently be lowered when the substrate is heated at a high temperature, and consequently it becomes difficult to obtain a MOSFET having desired channel mobility. Therefore, from a point of view of improvement in channel mobility of a MOSFET, a method for effectively lowering interface state density present in the region including the interface between the substrate and the gate oxide film by introducing nitrogen atoms while oxidation in the region above is suppressed is demanded.

### SUMMARY OF THE INVENTION

The present invention was made in view of the problems above, and an object thereof is to provide a method for manufacturing a semiconductor device capable of improving channel mobility.

A method for manufacturing a semiconductor device according to the present invention includes the steps of preparing a substrate composed of silicon carbide, forming a gate oxide film in contact with the substrate, and introducing nitrogen atoms in a region including an interface between the substrate and the gate oxide film. Then, in the step of introducing nitrogen atoms, nitrogen atoms are introduced in the region including the interface between the substrate and the gate oxide film by heating the substrate on which the gate oxide film has been formed in an atmospheric gas formed by heating a nitriding process gas containing nitrogen atoms but not containing oxygen atoms to a temperature exceeding 1200° C.

Here, with the method for manufacturing a semiconductor device according to the present invention, the nitriding process gas may be a gas composed of one gas or a plurality of gases containing nitrogen atoms but not containing oxygen atoms and an impurity as a remainder, and the gas may further contain one gas or a plurality of gases not containing nitrogen atoms and oxygen atoms.

In addition, in the method for manufacturing a semiconductor device according to the present invention, the substrate is heated in an atmospheric gas formed by heating a nitriding process gas substantially not containing oxygen atoms to a temperature exceeding 1200° C. Namely, in the method for manufacturing a semiconductor device according to the present invention, the substrate is not heated to a temperature not lower than 1200° C. in an atmospheric gas substantially containing oxygen atoms. Here, the nitriding process gas substantially not containing oxygen atoms refers to a gas in which a gas containing oxygen atoms is not intentionally introduced and includes a gas containing oxygen atoms as an impurity.

In the method for manufacturing a semiconductor device according to the present invention, in the step of introducing nitrogen atoms in the region including the interface between the substrate and the gate oxide film, the substrate is heated in the atmospheric gas formed by heating the nitriding process gas containing nitrogen atoms but not containing oxygen atoms to a temperature exceeding 1200° C. Therefore, even when the substrate is heated at a high temperature exceeding 1200° C., generation of oxygen due to decomposition of the nitriding process gas is suppressed and nitrogen atoms can be introduced in the region including the interface between the substrate and the gate oxide film while progress of oxidation is suppressed. Therefore, according to the method for manufacturing a semiconductor device in the present invention, a method for manufacturing a semiconductor device capable of improving channel mobility by lowering interface state density present in the region including the interface between the substrate and the gate oxide film by introducing nitrogen atoms in the region above can be provided.

In the method for manufacturing a semiconductor device above, in the step of introducing nitrogen atoms, nitrogen atoms may be introduced in the region including the interface between the substrate and the gate oxide film by heating the substrate in the atmospheric gas formed by heating the nitriding process gas to a temperature not higher than 1400° C.

Thus, the temperature to which the nitriding process gas is heated can be set within a range in which damage to the gate oxide film due to heating can be avoided.

In the method for manufacturing a semiconductor device above, in the step of introducing nitrogen atoms, nitrogen atoms may be introduced in the region including the interface between the substrate and the gate oxide film by heating the substrate in the atmospheric gas formed by heating the nitriding process gas composed of a gas containing nitrogen atoms but not containing oxygen atoms and a nitrogen gas as well as an impurity as a remainder.

Thus, owing to nitrogen generated from the gas above containing nitrogen atoms but not containing oxygen atoms, lowering in efficiency in introducing nitrogen atoms in the region including the interface between the substrate and the gate oxide film can be suppressed. Consequently, nitrogen atoms can more effectively be introduced in the region including the interface between the substrate and the gate oxide film.

In the method for manufacturing a semiconductor device above, in the step of introducing nitrogen atoms, nitrogen atoms may be introduced in the region including the interface between the substrate and the gate oxide film by heating the substrate in the atmospheric gas formed by heating the nitriding process gas containing NH₃. Thus, the nitriding process gas may be a gas containing NH₃, of which handling is relatively easy.

In the method for manufacturing a semiconductor device above, in the step of introducing nitrogen atoms, nitrogen atoms may be introduced in the region including the interface between the substrate and the gate oxide film by heating the substrate in the atmospheric gas formed by heating the nitriding process gas composed of NH₃ and N₂ as well as an impurity as a remainder.

Thus, owing to nitrogen generated from an NH₃ gas, lowering in efficiency in introducing nitrogen atoms in the region including the interface between the substrate and the gate oxide film can be suppressed. Consequently, nitrogen atoms can more effectively be introduced in the region including the interface between the substrate and the gate oxide film.

In the method for manufacturing a semiconductor device above, in the step of forming a gate oxide film, the gate oxide film may be formed to be in contact with a surface of the substrate, which is formed from a surface on a carbon face side of silicon carbide forming the substrate. In addition, in the method for manufacturing a semiconductor device above, in the step of forming a gate oxide film, the gate oxide film may be formed to be in contact with a surface of the substrate of which off angle with respect to a {0001} plane of silicon carbide forming the substrate is not smaller than 50° and not greater than 65°. Moreover, in the method for manufacturing a semiconductor device above, in the step of forming a gate oxide film, the gate oxide film may be formed to be in contact with a surface of the substrate, which is formed from a {11-20} plane of silicon carbide forming the substrate.

Since oxidation tends to proceed at the surface of the substrate formed from such a crystal plane, the method for manufacturing a semiconductor device according to the present invention can suitably be employed.

Here, a (0001) plane of hexagonal single crystal silicon carbide is defined as a silicon face, and a (000-1) plane thereof is defined as a carbon face. In addition, a surface on the carbon face side means a surface of which angle formed with respect to the (000-1) plane defined as the carbon face is not greater than 10°. Moreover, the surface of the substrate which is formed from the {11-20} plane means a surface of the substrate of which off angle with respect to the {11-20} plane of silicon carbide forming the substrate is not smaller than 0° and not greater than 10°.

In the method for manufacturing a semiconductor device above, in the step of introducing nitrogen atoms, nitrogen atoms may be introduced in the region including the interface between the gate oxide film and the substrate by heating the substrate arranged in a furnace having a core tube composed of silicon carbide formed with CVD.

Thus, by adopting a furnace having a core tube excellent in heat resistance in the step of introducing nitrogen atoms, the nitriding process gas is more readily heated to the temperature range above.

As is clear from the description above, according to the method for manufacturing a semiconductor device of the present invention, a method for manufacturing a semiconductor device capable of improving channel mobility can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flowchart schematically showing a method for manufacturing a MOSFET.

FIG. 2 is a schematic cross-sectional view for illustrating a method for manufacturing a MOSFET.

FIG. 3 is a schematic cross-sectional view for illustrating the method for manufacturing a MOSFET.

FIG. 4 is a schematic cross-sectional view for illustrating the method for manufacturing a MOSFET.

FIG. 5 is a schematic cross-sectional view for illustrating the method for manufacturing a MOSFET.

FIG. 6 is a schematic cross-sectional view for illustrating the method for manufacturing a MOSFET.

FIG. 7 is a schematic cross-sectional view for illustrating the method for manufacturing a MOSFET.

FIG. 8 is a schematic cross-sectional view for illustrating the method for manufacturing a MOSFET.

FIG. 9 is a schematic cross-sectional view for illustrating the method for manufacturing a MOSFET.

### DESCRIPTION OF THE PREFERRED EMBODIMENTS

An embodiment of the present invention will be described hereinafter with reference to the drawings. It is noted that, in the drawings below, the same or corresponding elements have the same reference characters allotted and description thereof will not be repeated. In addition, an individual orientation, a collective orientation, an individual plane, and a collective plane are herein shown in [ ], < >, ( ) and { }, respectively. Moreover, in terms of crystallography, a negative index should be denoted by a number with a bar “-” thereabove, however, a negative sign herein precedes a number.

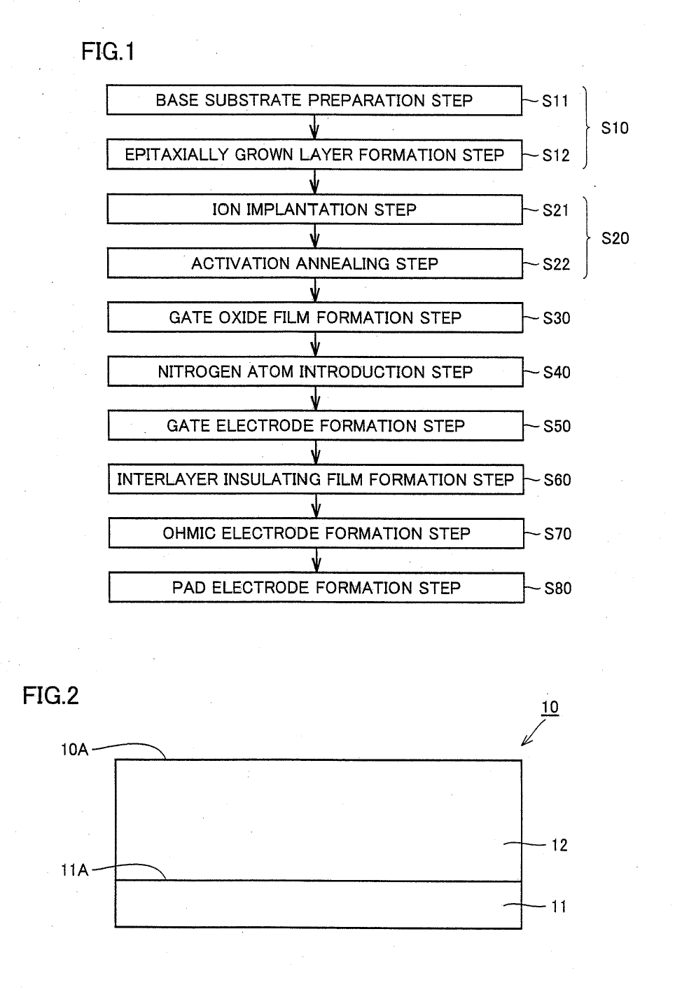

A method for manufacturing a semiconductor device according to one embodiment of the present invention will be described below. Referring to FIG. 1, initially, a substrate preparation step is performed as a step (S10). In this step (S10), steps (S11) and (S12) described below are performed to prepare a substrate 10 composed of silicon carbide and having a main surface 10A of which off angle with respect to the {0001} plane is not greater than 8°.

Initially, a base substrate preparation step is performed as the step (S11). In this step (S11), referring to FIG. 2, for example, a base substrate 11 composed of silicon carbide is prepared by slicing an ingot (not shown) composed of 4H-SiC.

Then, an epitaxially grown layer formation step is performed as the step (S12). In this step (S12), referring to FIG. 2, a semiconductor layer 12 is formed on a main surface 11A of base substrate 11 through epitaxial growth. Thus, substrate 10 including base substrate 11 and semiconductor layer 12 is prepared.

Then, an active region formation step is performed as a step (S20). In this step (S20), steps (S21) and (S22) described below are performed to form an active region in substrate 10.

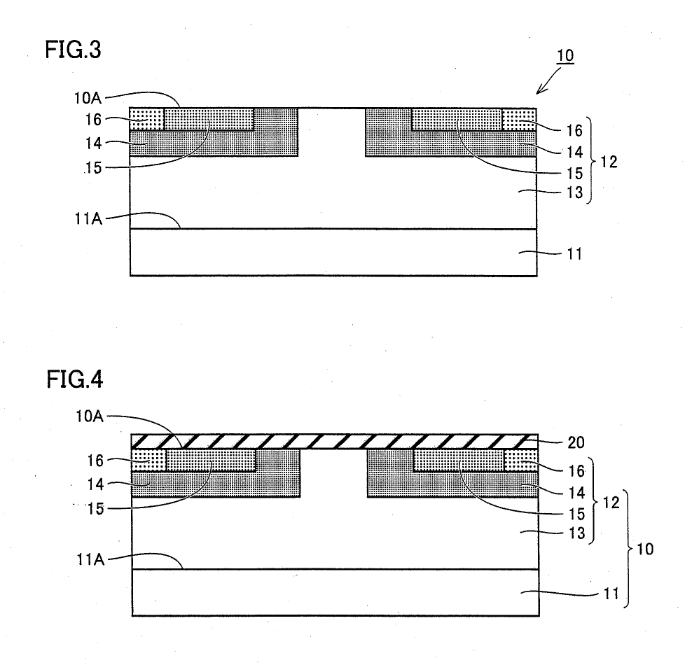

Initially, an ion implantation step is performed as the step (S21). In this step (S21), referring to FIG. 3, initially, for example, Al (aluminum) ions are implanted into a region including main surface 10A of substrate 10 to thereby form a p-type body region 14. Then, for example, P (phosphorus) ions are implanted into body region 14 to a depth of implantation smaller than a depth of implantation of Al (aluminum) ions above, to thereby form an n-type source region 15 in body region 14. Then, for example, Al (aluminum) ions are implanted into body region 14 to a depth of implantation as great as that of the P (phosphorus) ions above to thereby form a p-type contact region 16 adjacent to source region 15. A region in semiconductor layer 12 where none of body region 14, source region 15, and contact region 16 is formed serves as a drift region 13.

Then, an activation annealing step is performed as the step (S22). In this step (S22), the impurity introduced in the step (S21) above is activated by heating substrate 10. Thus, desired carriers are generated in the region where the impurity has been introduced. An active region is thus formed in substrate 10.

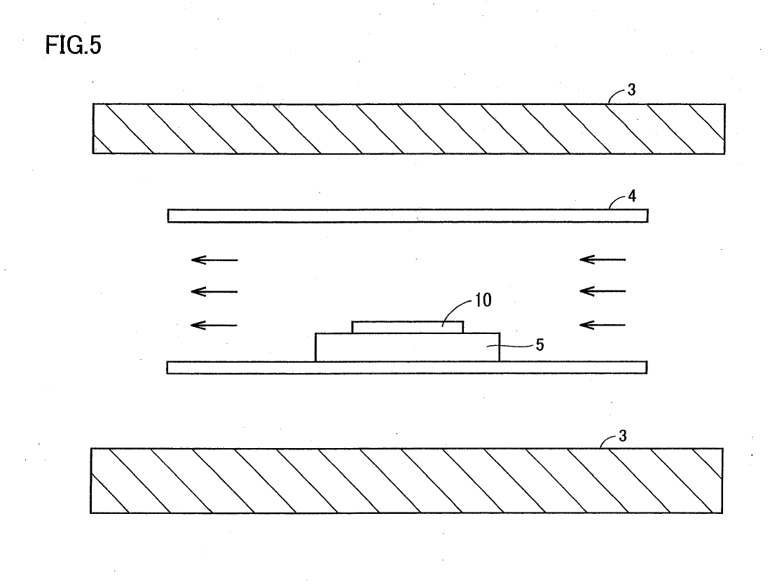

Then, a gate oxide film formation step is performed as a step (S30). In this step (S30), referring to FIG. 4, for example, by heating substrate 10 in an atmosphere containing oxygen, a gate oxide film 20 being in contact with main surface 10A of substrate 10 and composed of SiO₂ (silicon dioxide) is formed.

Then, a nitrogen atom introduction step is performed as a step (S40). In this step (S40), for example, substrate 10 on which gate oxide film 20 has been formed is heated in an atmospheric gas formed by heating a nitriding process gas containing nitrogen atoms but not containing oxygen atoms such as an NH₃ gas to a temperature exceeding 1200° C., so that nitrogen atoms are introduced in the region including the interface between substrate 10 and gate oxide film 20. Specifically, referring to FIG. 5, initially, substrate 10 is arranged on a support base 5 within a furnace 3 having a core tube 4 composed of silicon carbide formed with CVD (Chemical Vapor Deposition). Then, the nitriding process gas is introduced in core tube 4 as shown with an arrow in the figure. Then, substrate 10 is heated in the atmospheric gas formed by heating the nitriding process gas to a temperature exceeding 1200° C., so that nitrogen atoms are introduced in the region including the interface between substrate 10 and gate oxide film 20. Thus, by adopting furnace 3 having core tube 4 excellent in heat resistance in this step (S40), the nitriding process gas can more readily be heated to the temperature range above.

In addition, in this step (S40), substrate 10 may be heated in the atmospheric gas formed by heating the nitriding process gas to a temperature not higher than 1400° C. and more preferably a temperature not higher than 1300° C. Thus, the temperature to which the nitriding process gas is heated can be set within a range in which damage to gate oxide film 20 due to heating can be suppressed.

As described above, the nitriding process gas may contain an NH₃ gas of which handling is relatively easy, however, the nitriding process gas is not limited thereto. For example, the nitriding process gas may be a gas composed of an NH₃ gas and an N₂ gas as well as an impurity as a remainder. Here, a partial pressure of the NH₃ gas is set, for example, to be not lower than 6×10³ Pa and not higher than 6×10⁴ Pa. By thus adding the N₂ gas to the nitriding process gas to dilute the NH₃ gas, generation of the N₂ gas from the NH₃ gas can be suppressed. Thus, lowering in efficiency in introducing nitrogen atoms in the region including the interface between substrate 10 and gate oxide film 20 is suppressed and consequently nitrogen atoms can more effectively be introduced in the region including the interface between substrate 10 and gate oxide film 20. Furthermore, the nitriding process gas may include one gas or a plurality of gases of NH₃ and hydrazine as a gas containing nitrogen atoms but not containing oxygen atoms, and may further contain one gas or a plurality of gases of gases not containing nitrogen atoms and oxygen atoms, such as Ar (argon) and He (helium).

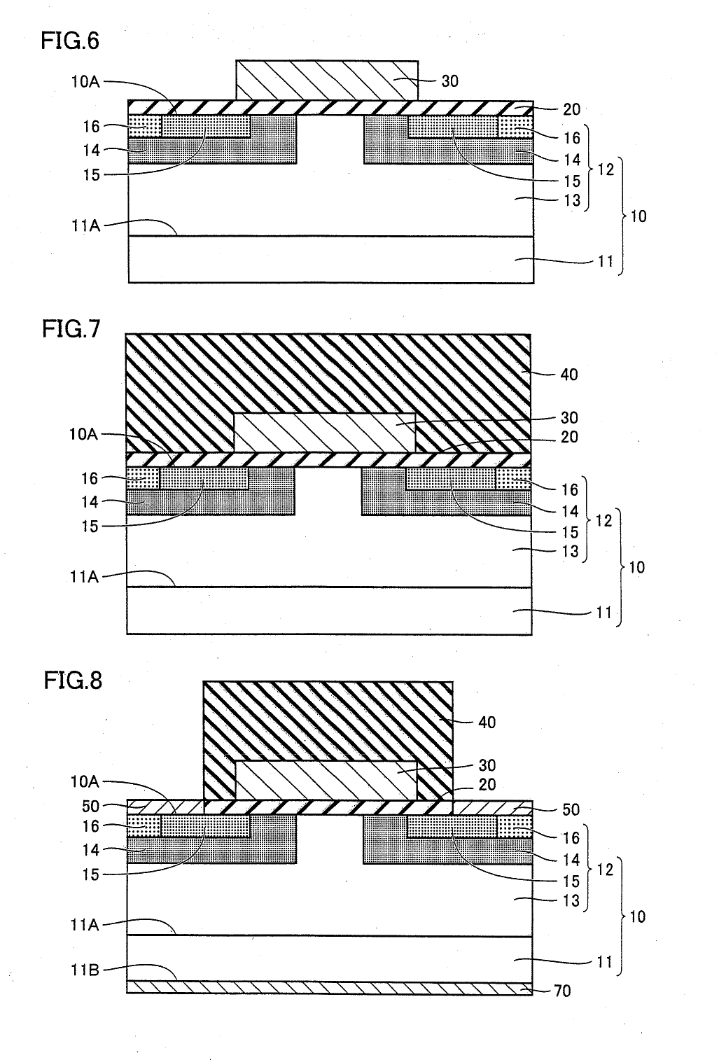

Then, a gate electrode formation step is performed as a step (S50). In this step (S50), referring to FIG. 6, a polysilicon film to which an impurity has been added is formed, for example, with LP (Low Pressure) CVD. Thus, a gate electrode 30 is formed on gate oxide film 20 in contact therewith, so as to extend from one body region 14 to the other body region 14 over the same.

Then, an interlayer insulating film formation step is performed as a step (S60). In this step (S60), referring to FIG. 7, an interlayer insulating film 40 composed of SiO₂ (silicon dioxide) is formed, for example, with CVD, so as to surround gate electrode 30 together with gate oxide film 20.

Then, an ohmic electrode formation step is performed as a step (S70). In this step (S70), referring to FIG. 8, initially, interlayer insulating film 40 and gate insulating film 20 are removed in a region where a source electrode 50 is to be formed, and a region where source region 15 and contact region 16 are exposed is formed. Then, a metal film composed, for example, of Ni is formed in that region. On the other hand, on a main surface 11B opposite to main surface 11A of base substrate 11, a metal film similarly composed of Ni is formed. Then, by heating the metal film above, at least a part of the metal film above is converted to silicide so that source electrode 50 and a drain electrode 70 electrically connected to substrate 10 are formed.

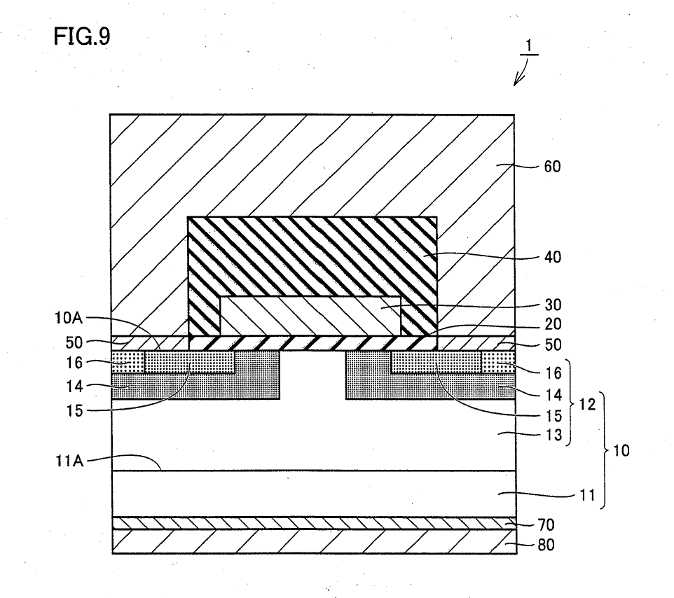

Then, a pad electrode formation step is performed as a step (S80). In this step (S80), referring to FIG. 9, for example, with a vapor deposition method, a source pad electrode 60 composed of such a conductor as Al (aluminum) is formed to cover source electrode 50 and interlayer insulating film 40. In addition, on drain electrode 70, similarly to source pad electrode 60, for example, with the vapor deposition method, a drain pad electrode 80 composed of such a conductor as Al (aluminum) is formed. As the steps (S10) to (S80) above are performed, a MOSFET 1 is manufactured and the method for manufacturing a semiconductor device according to the present embodiment is completed.

As above, with the method for manufacturing a semiconductor device according to the present embodiment, in the step (S40) of introducing nitrogen atoms in the region including the interface between substrate 10 and gate oxide film 20, substrate 10 is heated in an atmospheric gas formed by heating a nitriding process gas containing nitrogen atoms but not containing oxygen atoms to a temperature exceeding 1200° C. Therefore, even when substrate 10 is heated at a high temperature exceeding 1200° C., generation of oxygen due to decomposition of the nitriding process gas is suppressed and nitrogen atoms can be introduced in the region including the interface between substrate 10 and gate oxide film 20 while progress of oxidation is suppressed. Thus, the method for manufacturing a semiconductor device according to the present embodiment is a method for manufacturing a semiconductor device capable of improving channel mobility by lowering interface state density present in the region including the interface between substrate 10 and gate oxide film 20.

In addition, with the method for manufacturing a semiconductor device according to the present embodiment above, substrate 10 having main surface 10A on the carbon face side of silicon carbide forming substrate 10, substrate 10 having main surface 10A of which off angle with respect to the {0001} plane of silicon carbide forming substrate 10 is not smaller than 50° and not greater than 65°, or substrate 10 having main surface 10A which is formed from the {11-20} plane of silicon carbide forming substrate 10 may be prepared, and gate oxide film 20 may be formed to be in contact with main surface 10A. At main surface 10A of substrate 10 formed from such a crystal plane, oxidation of silicon carbide particularly tends to proceed. Therefore, the method for manufacturing a semiconductor device according to the present embodiment above capable of suppressing oxidation in the region including the interface between substrate 10 and gate oxide film 20 can suitably be employed. Furthermore, by forming gate oxide film 20 on main surface 10A of substrate 10 formed from such a crystal plane, channel mobility of MOSFET 1 can further be improved.

### Example 1

An experiment for confirming an effect of the method for manufacturing a semiconductor device according to the present invention was conducted in connection with relation between channel mobility of a MOSFET and a temperature to which a substrate was heated in the step of introducing nitrogen atoms in the region including the interface between the substrate and the gate oxide film. Initially, referring to FIGS. 2 to 4, with the method for manufacturing a semiconductor device according to the embodiment of the present invention, a substrate in which an active region had been formed was prepared and a gate oxide film was formed on the main surface of the substrate. In addition, a substrate having a main surface of which off angle with respect to the {0001} plane was not greater than 8° was prepared as the substrate. Then, the substrate on which the gate oxide film had been formed was heated in a nitriding process gas containing NH₃ at each temperature of 1150° C., 1200° C., 1250° C., and 1300° C. Then, referring to FIGS. 6 to 9, the MOSFET was completed with the method for manufacturing a semiconductor device according to the embodiment of the present invention, and channel mobility of the MOSFET in the case of manufacturing at each heating temperature was examined (Example 1). In addition, as a comparative example, channel mobility of the MOSFET was also similarly examined for the case where the substrate was heated in a nitriding process gas containing NO (Comparative Example 1). Table 1 shows relation between channel mobility of the MOSFET and a temperature to which the substrate was heated in the step of introducing nitrogen atoms in Example 1 and Comparative Example 1.

TABLE 1

| | | Plane Orientation | | Heating | |
|---|---|---|---|---|---|
| | | of Surface Where | | Temper- | |
| | | Oxide Film was | Process | ature | Mobility |
| Category | No. | Formed | Gas | (° C.) | (cm²/Vs) |
| Example 1 | 1 | (0001) Plane | NH₃ | 1150 | 31 |
| | 2 | (0001) Plane | NH₃ | 1200 | 38 |
| | 3 | (0001) Plane | NH₃ | 1250 | 40 |
| | 4 | (0001) Plane | NH₃ | 1300 | 45 |
| Comparative | 5 | (0001) Plane | NO | 1150 | 30 |
| Example 1 | 6 | (0001) Plane | NO | 1200 | 35 |
| | 7 | (0001) Plane | NO | 1250 | 38 |
| | 8 | (0001) Plane | NO | 1300 | 30 |

The results of the experiment above will be described below. As is clear from Table 1, in Comparative Example 1, when the substrate was heated at 1300° C., channel mobility lowered as compared with the case where the substrate was heated at a temperature not lower than 1150° C. and not higher than 1250° C., whereas in Example 1, channel mobility increased also with increase in temperature to which the substrate was heated in the temperature range not lower than 1150° C. and not higher than 1300° C. It was confirmed from this fact that, when the nitriding process gas containing NH₃ was adopted, channel mobility improved with increase in heating temperature in the range of the temperature to which the substrate was heated not lower than 1150° C. and not higher than 1300° C. in the step of introducing nitrogen atoms, and hence higher channel mobility could be achieved.

### Example 2

Then, an experiment for examining influence on channel mobility of a MOSFET by a plane orientation of a main surface of a substrate on which a gate oxide film was to be formed was conducted. Initially, as in Example 1, a substrate on which a gate oxide film had been formed was prepared. Here, in the present Example, a substrate having a {03-38} plane as the main surface was prepared and the gate oxide film was formed to be in contact with the main surface. Then, a MOSFET was completed as in Example 1, and channel mobility of the MOSFET in the case of manufacturing at each heating temperature was examined (Example 2). In addition, as a comparative example, channel mobility of the MOSFET was also similarly examined for the case where the substrate was heated in a nitriding process gas containing NO (Comparative Example 2). Table 2 shows relation between channel mobility of the MOSFET and a temperature to which the substrate was heated in the step of introducing nitrogen atoms in Example 2 and Comparative Example 2.

TABLE 2

| | | Plane Orientation | | Heating | |
|---|---|---|---|---|---|
| | | of Surface Where | | Temper- | |
| | | Oxide Film was | Process | ature | Mobility |
| Category | No. | Formed | Gas | (° C.) | (cm²/Vs) |
| Example 2 | 1 | {03-38} Plane | NH₃ | 1150 | 80 |
| | 2 | {03-38} Plane | NH₃ | 1200 | 95 |
| | 3 | {03-38} Plane | NH₃ | 1250 | 110 |
| | 4 | {03-38} Plane | NH₃ | 1300 | 120 |
| Comparative | 5 | {03-38} Plane | NO | 1150 | 75 |
| Example 2 | 6 | {03-38} Plane | NO | 1200 | 90 |
| | 7 | {03-38} Plane | NO | 1250 | 95 |
| | 8 | {03-38} Plane | NO | 1300 | 80 |

The results of the experiment above will be described below. As is clear from Table 2, as in Example 1 and Comparative Example 1 above, in Comparative Example 2, when the substrate was heated at 1300° C., channel mobility lowered as compared with the case where the substrate was heated at a temperature not lower than 1150° C. and not higher than 1250° C., whereas in Example 2, channel mobility increased also with increase in temperature to which the substrate was heated in the temperature range not lower than 1150° C. and not higher than 1300° C. It was confirmed from this fact that, even when the gate oxide film was formed on the main surface which was formed from the {03-38} plane, by adopting a nitriding process gas containing NH₃, channel mobility improved with increase in heating temperature in the temperature range not lower than 1150° C. and not higher than 1300° C., and hence higher channel mobility could be achieved.

The method for manufacturing a semiconductor device according to the present invention can particularly advantageously be applied to a method for manufacturing a semiconductor device required to achieve improved channel mobility.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a semiconductor device, comprising the steps or:
preparing a substrate composed of silicon carbide;
forming a gate oxide film in contact with said substrate; and
introducing nitrogen atoms in a region including an interface between said substrate and said gate oxide film,
in said step of introducing nitrogen atoms, nitrogen atoms being introduced in the region including the interface between said substrate and said gate oxide film by heating said substrate on which said gate oxide film has been formed in an atmospheric gas formed by heating a nitriding process gas containing nitrogen atoms but not containing oxygen atoms to a temperature exceeding 1200° C.

2. The method for manufacturing a semiconductor device according to claim 1, wherein
in said step of introducing nitrogen atoms, nitrogen atoms are introduced in the region including the interface between said substrate and said gate oxide film by heating said substrate in said atmospheric gas formed by heating said nitriding process gas to a temperature not higher than 1400° C.

3. The method for manufacturing a semiconductor device according to claim 1, wherein
in said step of introducing nitrogen atoms, nitrogen atoms are introduced in the region including the interface between said substrate and said gate oxide film by heating said substrate in said atmospheric gas formed by heating said nitriding process gas composed of a gas containing nitrogen atoms but not containing oxygen atoms and a nitrogen gas as well as an impurity as a remainder.

4. The method for manufacturing a semiconductor device according to claim 1, wherein
in said step of introducing nitrogen atoms, nitrogen atoms are introduced in the region including the interface between said substrate and said gate oxide film by heating said substrate in said atmospheric gas formed by heating said nitriding process gas containing NH₃.

5. The method for manufacturing a semiconductor device according to claim 1, wherein
in said step of introducing nitrogen atoms, nitrogen atoms are introduced in the region including the interface between said substrate and said gate oxide film by heating said substrate in said atmospheric gas formed by heating said nitriding process gas composed of NH₃ and N₂ as well as an impurity as a remainder.

6. The method for manufacturing a semiconductor device according to claim 1, wherein
in said step of forming a gate oxide film, said gate oxide film is formed to be in contact with a surface of said substrate, which is formed from a surface on a carbon face side of silicon carbide forming said substrate.

7. The method for manufacturing a semiconductor device according to claim 1, wherein
in said step of forming a gate oxide film, said gate oxide film is formed to be in contact with a surface of said substrate of which off angle with respect to a {0001} plane of silicon carbide forming said substrate is not smaller than 50° and not greater than 65°.

8. The method for manufacturing a semiconductor device according to claim 1, wherein
in said step of forming a gate oxide film, said gate oxide film is formed to be in contact with a surface of said substrate, which is formed from a {11-20} plane of silicon carbide forming said substrate.

9. The method for manufacturing a semiconductor device according to claim 1, wherein
in said step of introducing nitrogen atoms, nitrogen atoms are introduced in the region including the interface between said substrate and said gate oxide film by heating said substrate arranged in a furnace having a core tube composed of silicon carbide formed with CVD.
